(19) United States
(12) Patent Application Publication
(10) Pub. No.: US 2025/0212604 A1
(43) Pub. Date: Jun. 26, 2025

(54) DISPLAY APPARATUS AND METHOD OF MANUFACTURING THE SAME

(71) Applicant: Samsung Display Co., Ltd., Yongin-Si (KR)

(72) Inventors: Keunwoo Kim, Yongin-si (KR); Taesang Kim, Yongin-si (KR); Joonseok Park, Yongin-si (KR); Bummo Sung, Yongin-si (KR); Hyelim Choi, Yongin-si (KR)

(21) Appl. No.: 18/740,514

(22) Filed: Jun. 12, 2024

(30) Foreign Application Priority Data
Dec. 20, 2023 (KR) 10-2023-0187564

(51) Int. Cl. H10K 59/121; H01L 27/12; H10K 59/12; H10K 59/131

(52) U.S. Cl. CPC H10K 59/1213; H10K 59/1201; H10K 59/131; H10D 86/0221; H10D 86/423; H10D 86/60

(57) ABSTRACT

Provided is a display apparatus including a substrate, a first thin-film transistor disposed over the substrate and including a first semiconductor layer and a first gate electrode, a second thin-film transistor including a second semiconductor layer and a second gate electrode, a first insulating layer between the first semiconductor layer and the first gate electrode, a second insulating layer between the first gate electrode and the second semiconductor layer, a third insulating layer between the second semiconductor layer and the second gate electrode, a fourth insulating layer on the second gate electrode, a first hole above the first semiconductor layer and passing through the first insulating layer and the second insulating layer, and a second hole within the first hole and passing through the third insulating layer and the fourth insulating layer.

### CROSS-REFERENCE TO RELATED APPLICATION

This application is based on and claims priority under 35 U.S.C. § 119 to Korean Patent Application No. 10-2023-0187564, filed on Dec. 20, 2023, in the Korean Intellectual Property Office, the disclosure of which is incorporated by reference herein in its entirety.

### BACKGROUND

### 1. Field

One or more embodiments relate to a display apparatus and a method of manufacturing the display apparatus.

### 2. Description of the Related Art

A display apparatus visually displays data. A display apparatus is used as a display unit of miniaturized products, such as mobile phones, and as a display unit of large-scale products, such as televisions.

A display apparatus includes a plurality of sub-pixels that receive electrical signals and emit light to display images to the outside. Each sub-pixel includes a display element. As an example, an organic light-emitting display apparatus includes an organic light-emitting diode as a display element. Generally, an organic light-emitting display apparatus includes transistors and an organic light-emitting diode over a substrate, and operates while the organic light-emitting diode emits light spontaneously.

Recently, as the purpose of use of display apparatuses has diversified, various attempts have been made to design display apparatuses with improved quality.

### SUMMARY

One or more embodiments include a display apparatus with improved characteristics of transistors, and a method of manufacturing the display apparatus. However, such a technical feature is just an example, and the disclosure is not limited thereto.

Additional aspects will be set forth in part in the description which follows and, in part, will be apparent from the description, or may be learned by practice of the presented embodiments of the disclosure.

According to one or more embodiments, a display apparatus includes a substrate, a first thin-film transistor disposed over the substrate and including a first semiconductor layer and a first gate electrode, a second thin-film transistor including a second semiconductor layer and a second gate electrode, a first insulating layer between the first semiconductor layer and the first gate electrode, a second insulating layer between the first gate electrode and the second semiconductor layer, a third insulating layer between the second semiconductor layer and the second gate electrode, a fourth insulating layer on the second gate electrode, a first hole above the first semiconductor layer and passing through the first insulating layer and the second insulating layer, and a second hole within the first hole and passing through the third insulating layer and the fourth insulating layer.

A width of the first hole may be greater than a width of the second hole.

The second thin-film transistor may further include a third gate electrode disposed below the second semiconductor layer and overlapping the second semiconductor layer, and the second insulating layer may include a second-1 insulating layer and a second-2 insulating layer, wherein the second-1 insulating layer is between the first gate electrode and the third gate electrode, and the second-2 insulating layer is on the third gate electrode.

The display apparatus may further include a fifth insulating layer between the second insulating layer and the second semiconductor layer, wherein the fifth insulating layer may fill at least a portion of the first hole.

The fifth insulating layer may include an inorganic insulating material.

The display apparatus may further include an electrode disposed on the fourth insulating layer and overlapping the first semiconductor layer, wherein the electrode may be in contact with the first semiconductor layer through the second hole.

The electrode may be in contact with the fifth insulating layer filling the at least portion of the first hole.

The first semiconductor layer may include a silicon semiconductor material, and the second semiconductor layer may include an oxide semiconductor material.

The display apparatus may further include an oxide layer disposed on the first semiconductor layer and disposed in the first hole.

The second hole may pass through the oxide layer.

According to one or more embodiments, a method of manufacturing a display apparatus includes forming a first semiconductor layer of a first thin-film transistor over a substrate, forming a first insulating layer on the first semiconductor layer, forming a first gate electrode of the first thin-film transistor on the first insulating layer, forming a second insulating layer on the first gate electrode, forming a first hole above the first semiconductor layer and passing through the first insulating layer and the second insulating layer, heat-treating the first semiconductor layer, forming a second semiconductor layer of a second thin-film transistor on the second insulating layer, forming a third insulating layer on the second semiconductor layer, forming a second gate electrode of the second thin-film transistor on the third insulating layer, forming a fourth insulating layer on the second gate electrode, and forming a second hole within the first hole and passing through the third insulating layer and the fourth insulating layer.

A width of the first hole may be greater than a width of the second hole.

The method may further include forming a third gate electrode of the second thin-film transistor disposed below the second semiconductor layer and overlapping the second semiconductor layer, wherein the forming of the second insulating layer may include forming a second-1 insulating layer between the first gate electrode and the third gate electrode, and forming a second-2 insulating layer on the third gate electrode.

The method may further include forming a fifth insulating layer between the second insulating layer and the second semiconductor layer, wherein the fifth insulating layer may fill at least a portion of the first hole.

The fifth insulating layer may include an inorganic insulating material.

The second hole may pass through the fifth insulating layer filling at least a portion of the first hole.

The method may further include forming an electrode overlapping the first semiconductor layer on the fourth insulating layer, wherein the electrode may be in contact with the first semiconductor layer through the second hole.

The electrode may be in contact with the fifth insulating layer filling the at least portion of the first hole.

The method may further include, before the forming of the second semiconductor layer, forming an oxide layer on the first semiconductor layer and disposed in the first hole.

The second hole may pass through the oxide layer.

### BRIEF DESCRIPTION OF THE DRAWINGS

The above and other aspects, features, and advantages of certain embodiments of the disclosure will be more apparent from the following description taken in conjunction with the accompanying drawings.

FIG. 1 is a schematic plan view of a display apparatus according to an embodiment.

FIG. 2 is a schematic equivalent circuit diagram of a light-emitting diode of a display apparatus and a sub-pixel circuit electrically connected thereto according to an embodiment.

FIG. 3 is a schematic cross-sectional view of the display apparatus of FIG. 1 taken along line I-I′, according to an embodiment.

FIG. 4 is a plan view of a first hole and a first contact hole of a display apparatus according to an embodiment.

FIGS. 5A, 5B, 5C, 5D, and 5E are cross-sectional views showing a process of manufacturing a display apparatus according to an embodiment.

FIG. 6 is a schematic cross-sectional view of the display apparatus according to an embodiment.

FIGS. 7A, 7B, 7C, and 7D are cross-sectional views showing a process of manufacturing a display apparatus according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain embodiments will be illustrated in the drawings and described in the written description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described with reference to the accompanying drawings, wherein like reference numerals refer to like elements throughout and a repeated description thereof is omitted.

While such terms as “first” and “second” may be used to describe various components, such components must not be limited to the above terms. The above terms are used to distinguish one component from another.

The singular forms “a,” “an,” and “the” as used herein are intended to include the plural forms as well unless the context clearly indicates otherwise.

It will be understood that the terms “comprise,” “comprising,” “include” and/or “including” as used herein specify the presence of stated features or components but do not preclude the addition of one or more other features or components.

It will be further understood that, when a layer, region, or element is referred to as being “on” another layer, region, or element, it can be directly or indirectly on the other layer, region, or element. That is, for example, intervening layers, regions, or elements may be present.

Sizes of elements in the drawings may be exaggerated or reduced for convenience of explanation. As an example, the size and thickness of each element shown in the drawings are arbitrarily represented for convenience of description, and thus, the disclosure is not necessarily limited thereto.

In the case where a certain embodiment may be implemented differently, a specific process order may be performed in the order different from the described order. As an example, two processes successively described may be simultaneously performed substantially and performed in the opposite order.

In the present specification, “A and/or B” means A or B, or A and B. In the present specification, “at least one of A and B” means A or B, or A and B.

It will be understood that when a layer, region, or element is referred to as being “connected” to another layer, region, or element, it may be “directly connected” to the other layer, region, or element or may be “indirectly connected” to the other layer, region, or element with another layer, region, or element located therebetween. For example, it will be understood that when a layer, region, or element is referred to as being “electrically connected” to another layer, region, or element, it may be “directly electrically connected” to the other layer, region, or element or may be “indirectly electrically connected” to the other layer, region, or element with another layer, region, or element interposed therebetween.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different orientations that are not perpendicular to one another.

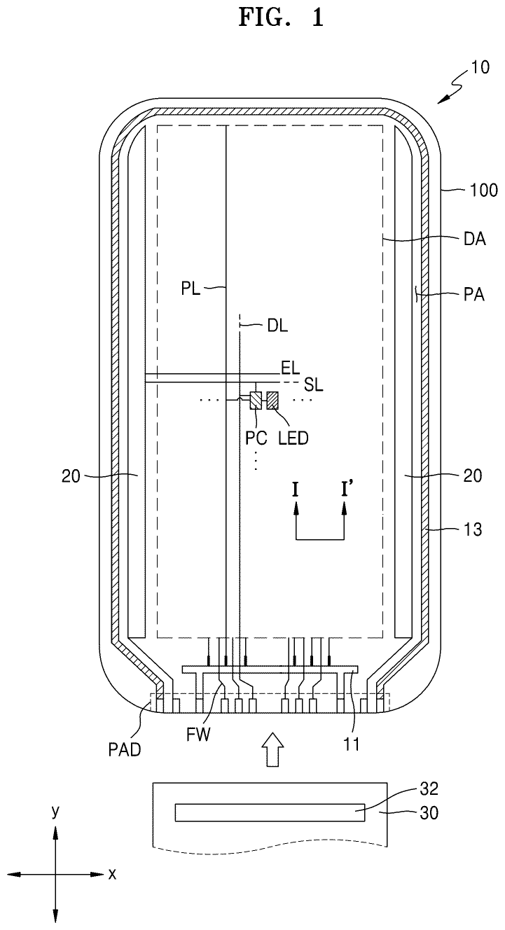

FIG. 1 is a schematic plan view of a display apparatus 10 according to an embodiment.

Referring to FIG. 1, various elements constituting the display apparatus 10 are disposed on a substrate 100. The substrate 100 includes a display area DA and a peripheral area PA surrounding the display area DA. The display area DA may be covered by an encapsulation member for protection from external air, moisture, or the like.

Light-emitting diodes LED are arranged in the display area DA of the substrate 100. The display apparatus 10 may be configured to display images by using light emitted from the light-emitting diodes LED. Each light-emitting diode LED may be configured to emit, for example, red, green, or blue light.

In an embodiment, the light-emitting diode LED may include an organic light-emitting diode including an organic material as a light-emitting material. In an embodiment, the light-emitting diode LED may be an inorganic light-emitting diode including an inorganic material. The inorganic light-emitting diode may include a PN-junction diode including inorganic material semiconductor-based materials. When a forward voltage is applied to a PN-junction diode, holes and electrons are injected and energy created by recombination of the holes and the electrons is converted to light energy, and thus, light of a preset color may be emitted.

The size of the light-emitting diode LED may be microscales or nanoscales. As an example, the light-emitting diode LED may be a micro light-emitting diode. In other embodiments, the light-emitting diode LED may be a nanorod light-emitting diode. The nanorod light-emitting diode may include gallium nitride (GaN).

In an embodiment, the light-emitting diode LED may be a quantum-dot light-emitting diode. As described above, an emission layer of the light-emitting diode LED may include an organic material, an inorganic material, quantum dots, an organic material and quantum dots, or inorganic material and quantum dots. Hereinafter, for convenience of description, the case where the light-emitting diode LED includes an organic light-emitting diode is described.

Each light-emitting diode LED may be electrically connected to a sub-pixel circuit PC, and each sub-pixel circuit PC may include transistors and a capacitor. The sub-pixel circuits PC may each be electrically connected to peripheral circuits arranged in the peripheral area PA. Peripheral circuits arranged in the peripheral area PA may include a scan driving circuit 20, a terminal part PAD, a driving voltage supply line 11, and common voltage supply lines 13.

The scan driving circuit 20 may be configured to provide scan signals to each of the sub-pixel circuits PC through a scan line SL and provide emission control signals to each of the sub-pixel circuits PC through an emission control line EL. The scan driving circuits 20 may be arranged on two opposite sides around the display area DA. The sub-pixel circuit PC arranged in the display area DA may be electrically connected to at least one of the scan driving circuits 20 provided to the left side or the right side.

The terminal part PAD may be arranged on one side of the substrate 100. The terminal part PAD may be exposed and connected to a display circuit board 30 by not being covered by an insulating layer. A display driver 32 may be arranged on the display circuit board 30.

The display driver 32 may be configured to generate control signals transferred to the scan driving circuit 20. The display driver 32 may be configured to generate a data signal, and the generated data signal may be transferred to the sub-pixel circuit PC through a fan-out wiring FW and a data line DL connected to the fan-out wiring FW.

The display driver 32 may be configured to supply a driving voltage ELVDD to the driving voltage supply line 11 and supply a common voltage ELVSS to the common voltage supply line 13. The driving voltage ELVDD may be applied to the sub-pixel circuit PC through the driving voltage line PL connected to the supply line 11, and the common voltage ELVSS may be applied to an opposite electrode (e.g., a cathode) of the light-emitting diode LED through the common voltage supply line 13.

The driving voltage supply line 11 may extend in an x direction below the display area DA. The common voltage supply line 13 may have a loop shape having one open side to partially surround the display area DA.

The display apparatus 10 of FIG. 1 is an apparatus for displaying moving images or still images and may include portable electronic apparatuses such as mobile phones, smartphones, tablet personal computers, mobile communication terminals, electronic organizers, electronic books, portable multimedia players (PMPs), navigations, and ultra mobile personal computers (UMPCs), and the like. In other embodiments, the display apparatus 10 may be used as a display screen of various products including televisions, notebook computers, monitors, advertisement boards, Internet of things (IoTs), and the like. In addition, the display apparatus 10 according to an embodiment may be used in wearable devices including smartwatches, watchphones, glasses-type displays, and head-mounted displays (HMDs). In addition, in an embodiment, the display apparatus 10 is applicable to a display screen in instrument panels for automobiles, center fascias for automobiles, or center information displays (CIDs) arranged on a dashboard, room mirror displays that replace side mirrors of automobiles, and displays of an entertainment system arranged on the backside of front seats for backseat passengers in automobiles.

In an embodiment, the display apparatus 10 may be a foldable display apparatus. As an example, the display apparatus 10 may be folded around a folding axis extending in a first direction (e.g., the x direction) or a second direction (e.g., a y direction).

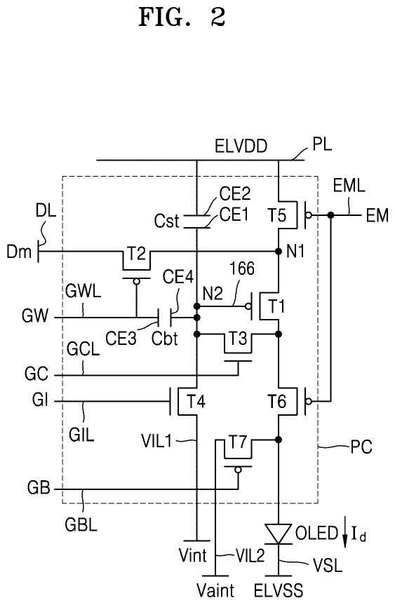

FIG. 2 is a schematic equivalent circuit diagram of a light-emitting diode of the display apparatus 10 and a sub-pixel circuit electrically connected thereto according to an embodiment.

Referring to FIG. 2, the light-emitting diode may be electrically connected to a sub-pixel circuit PC, wherein the sub-pixel circuit PC includes a plurality of transistors and a capacitor. In an embodiment, the light-emitting diode may be an organic light-emitting diode OLED.

As an example, the sub-pixel circuit PC may include a plurality of thin-film transistors T1, T2, T3, T4, T5, T6, and T7, a first capacitor Cst, and a second capacitor Cbt. In an embodiment, the plurality of thin-film transistors T1, T2, T3, T4, T5, T6, and T7 may include a driving transistor T1, a switching transistor T2, a compensation transistor T3, a first initialization transistor T4, an operation control transistor T5, an emission control transistor T6, and a second initialization transistor T7. In an embodiment, the first capacitor Cst may be a storage capacitor, and the second capacitor Cbt may be a boost capacitor. However, the embodiment is not limited thereto. In an embodiment, the sub-pixel circuit PC may not include the second capacitor Cbt.

The organic light-emitting diode OLED may include a sub-pixel electrode and an opposite electrode. The sub-pixel electrode of the organic light-emitting diode OLED may be connected to the driving transistor T1 through the emission control transistor T6 and may receive a driving current I_{d}, and the opposite electrode may be configured to receive the common voltage ELVSS. The organic light-emitting diode OLED may be configured to generate light of brightness corresponding to the driving current I_{d}.

In an embodiment, some of the plurality of thin-film transistors T1, T2, T3, T4, T5, T6, and T7 may be n-channel metal-oxide semiconductor (NMOS) field-effect transistors (n-channel MOSFETs), and the rest may be p-channel metal-oxide semiconductor (PMOS) field-effect transistors (p-channel MOSFETs). As an example, as shown in FIG. 2, among the plurality of thin-film transistors T1, T2, T3, T4, T5, T6, and T7, the compensation transistor T3 and the first initialization transistor T4 may be n-channel MOSFETs (NMOSs), and the rest may be p-channel MOSFETs (PMOSs).

The signal lines may include a first scan line GWL, a second scan line GCL, a third scan line GIL, an emission control line EML, a fourth scan line GBL, and the data line DL. The first scan line GWL is configured to transfer a first scan signal GW, the second scan line GCL is configured to transfer a second scan signal GC, the third scan line GIL is configured to transfer a third scan signal GI to the first initialization thin-film transistor T4, the emission control line EML is configured to transfer an emission control signal EM to the operation control thin-film transistor T5 and the emission control thin-film transistor T6, the fourth scan line GBL is configured to transfer a fourth scan signal GB to the second initialization thin-film transistor T7, and the data line DL is configured to transfer a data signal Dm.

The driving voltage line PL may be configured to transfer the driving voltage ELVDD to the driving transistor T1. The driving voltage line PL may be configured to transfer the driving voltage ELVDD to the driving transistor T1. A first initialization voltage line VIL1 may be configured to transfer a first initialization voltage Vint to the sub-pixel circuit PC, wherein the first initialization voltage Vint initializes the driving transistor T1. A second initialization voltage line VIL2 may be configured to transfer a second initialization voltage Vaint to the sub-pixel circuit PC, wherein the second initialization voltage Vaint initializes the organic light-emitting diode OLED. Specifically, the first initialization voltage line VIL1 may be configured to transfer the first initialization voltage Vint to the first initialization transistor T4, and the second initialization voltage line VIL2 may be configured to transfer the second initialization voltage Vaint to the second initialization transistor T7.

In an embodiment, the signal lines, the first initialization voltage line VIL1, the second initialization voltage line VIL2, the driving voltage line PL, and the common voltage line VSL may be shared by sub-pixel circuits.

A gate electrode of the driving transistor T1 may be connected to the first capacitor Cst and the second capacitor Cbt via a second node N2, one of a source region and a drain region of the driving transistor T1 may be connected to the driving voltage line PL through the operation control transistor T5 via a first node N1, and the other of the source region and the drain region of the driving transistor T1 may be electrically connected to the sub-pixel electrode of the organic light-emitting diode OLED through the emission control transistor T6. The driving transistor T1 may be configured to receive the data signal Dm and supply the driving current la to the organic light-emitting diode OLED according to a switching operation of the switching transistor T2.

A gate electrode of the switching transistor T2 may be connected to the first scan line GWL configured to transfer a first scan signal GW and the second capacitor Cbt, one of a source region and a drain region of the switching transistor T2 may be connected to the data line DL, and the other of the source region and the drain region of the switching transistor T2 may be connected to the driving transistor T1 through the first node N1 and connected to the driving voltage line PL through the operation control transistor T5. The switching transistor T2 may perform a switching operation of being turned on according to a first scan signal GW transferred through the first scan line GWL and transferring a data signal Dm to the driving transistor T1 through the first node N1, the data signal Dm being transferred through the data line DL.

A gate electrode of the compensation transistor T3 is connected to the second scan line GCL. One of a source region and a drain region of the compensation transistor T3 may be connected to the sub-pixel electrode of the organic light-emitting diode OLED through the emission control transistor T6. The other of the source region and the drain region of the compensation transistor T3 may be connected to the first capacitor Cst and the gate electrode of the driving transistor T1 through a node connection line 166. The compensation transistor T3 may be turned on according to the second scan signal GC to compensate for a threshold voltage of the driving transistor T1 by diode-connecting the driving transistor T1, wherein the second scan signal GC is transferred through the second scan line GCL.

A gate electrode of the first initialization transistor T4 may be connected to the third scan line GIL. One of a source region and a drain region of the first initialization transistor T4 may be connected to the first initialization voltage line VIL1. The other of the source region and the drain region of the first initialization transistor T4 may be connected to a first capacitor electrode CE1 of the first capacitor Cst, and the gate electrode of the driving transistor T1. The first initialization transistor T4 may be turned on according to a third scan signal GI received through the third scan line GIL and may initialize the voltage of the gate voltage of the driving transistor T1 by transferring the first initialization voltage Vint to the gate electrode of the driving transistor T1.

A gate electrode of the operation control transistor T5 may be connected to the emission control line EML, one of a source region and a drain region of the operation control transistor T5 may be connected to the driving voltage line PL, and the other of the source region and the drain region of the operation control transistor T5 may be connected to the driving transistor T1 and the switching transistor T2 through the first node N1.

A gate electrode of the emission control transistor T6 may be connected to the emission control line EML, one of a source region and a drain region of the emission control transistor T6 may be connected to the driving transistor T1 and the compensation transistor T3, and the other of the source region and the drain region of the emission control transistor T6 may be electrically connected to the sub-pixel electrode of the organic light-emitting diode OLED.

The operation control transistor T5 and the emission control transistor T6 may be simultaneously turned on according to an emission control signal EM transferred through the emission control line EML, and may form a current path such that the driving current I_{d} flows in a direction from the driving voltage line PL to the organic light-emitting diode OLED.

A gate electrode of the second initialization transistor T7 may be connected to the fourth scan line GBL, one of a source region and a drain region of the second initialization transistor T7 may be connected to the sub-pixel electrode of the organic light-emitting diode OLED, and the other of the source region and the drain region of the second initialization transistor T7 may be electrically connected to the second initialization voltage line VIL2 to receive the second initialization voltage Vaint. The second initialization transistor T7 may be turned on according to the fourth scan signal GB transferred through the fourth scan line GBL and may initialize the sub-pixel electrode of the organic light-emitting diode OLED.

In an embodiment, the fourth scan signal GB may be substantially synchronized with the first scan signal GW. In an embodiment, the fourth scan signal GB may be substantially synchronized with the first scan signal GW of a pixel located in a next row. As an example, the fourth scan line GBL may be substantially the same as the first scan line GWL of a sub-pixel in a next row.

The first capacitor Cst may include the first capacitor electrode CE1 and a second capacitor electrode CE2. The first capacitor electrode CE1 may be connected to the gate electrode of the driving transistor T1, and the second capacitor electrode CE2 may be connected to the driving voltage line PL. The first capacitor Cst may maintain a voltage applied to the gate electrode of the driving transistor T1 by storing and maintaining a voltage corresponding to a difference between voltages of two opposite ends of the gate electrode of the driving transistor T1 and the driving voltage line PL.

The second capacitor Cbt may include a third capacitor electrode CE3 and a fourth capacitor electrode CE4. The third capacitor electrode CE3 may be connected to the first scan line GWL and the gate electrode of the switching transistor T2. The fourth capacitor electrode CE4 may be connected to the gate electrode of the driving transistor T1 and the first capacitor electrode CE1 of the first capacitor Cst. The second capacitor Cbt serves as a boost capacitor. When a first scan signal GW of the first scan line GWL is a voltage that turns off the switching transistor T2, the second capacitor Cbt may be configured to clearly express a black grayscale by increasing the voltage of the second node N2.

In an embodiment, at least one of the plurality of thin-film transistors T1, T2, T3, T4, T5, T6, and T7 may include a semiconductor layer including oxide, and the rest may include a semiconductor layer including amorphous silicon or polycrystalline silicon.

Specifically, the driving transistor T1 directly influencing the brightness of the display apparatus may be configured to include a semiconductor layer including polycrystalline silicon having high reliability, and thus, a high-resolution display apparatus may be implemented through this configuration.

Because the oxide semiconductor has a high carrier mobility and a low leakage current, a voltage drop may not be large even though a driving time is long. That is, because a color change of an image according to a voltage drop is not large even while the display apparatus is driven in low frequencies, the display apparatus may be driven in low frequencies.

Because the oxide semiconductor has an advantage of a low leakage current, at least one of the compensation transistor T3, the first initialization transistor T4, and the second initialization transistor T7 connected to the gate electrode of the driving transistor T1 may include an oxide semiconductor, and thus, a leakage current that may flow to the gate electrode of the driving transistor T1 may be prevented, and simultaneously, power consumption may be reduced.

In an embodiment, as shown in FIG. 2, the compensation transistor T3 and the first initialization transistor T4 may include an oxide semiconductor, and accordingly, the power consumption of the display apparatus 10 may be improved even more.

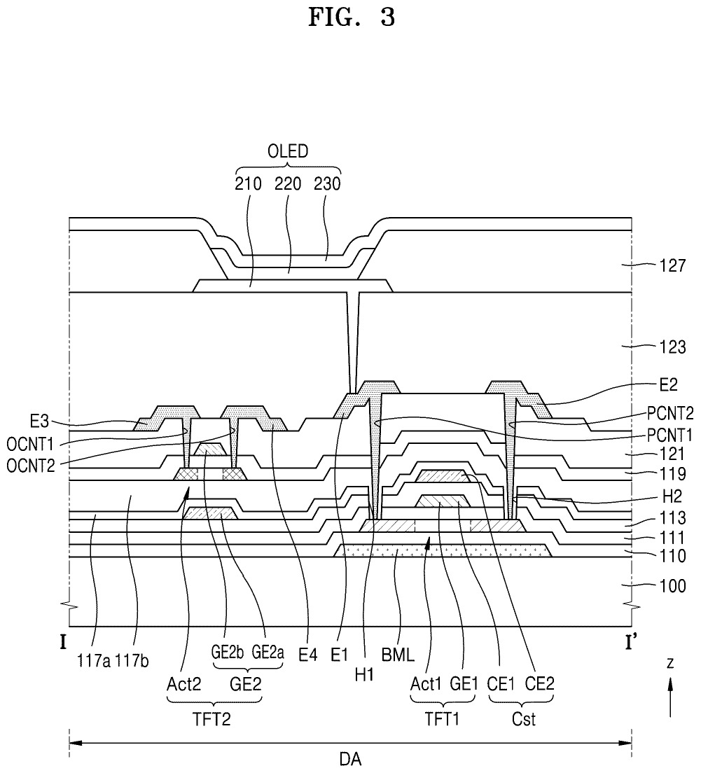

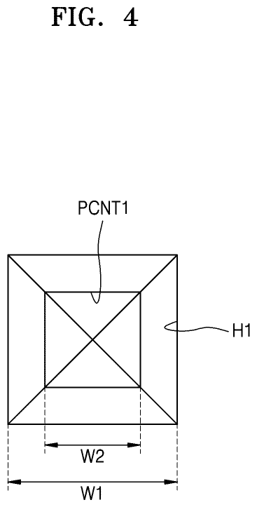

FIG. 3 is a schematic cross-sectional view of the display apparatus 10, taken along line I-I′ of FIG. 1, according to an embodiment. In addition, FIG. 4 is a plan view of a first hole H1 and a first contact hole PCNT1 of the display apparatus 10 according to an embodiment.

Referring to FIG. 3, a first thin-film transistor TFT1, a second thin-film transistor TFT2, and the first capacitor Cst may be arranged in the display area DA. The first thin-film transistor TFT1 may correspond to the driving transistor T1 of FIG. 2, the second thin-film transistor TFT2 may correspond to the compensation transistor T3 and the first initialization transistor T4 of FIG. 2. In an embodiment, the first thin-film transistor TFT1 may be provided as a p-channel MOSFET, and the second thin-film transistor TFT2 may be provided as an n-channel MOSFET.

The first thin-film transistor TFT1 may include a first semiconductor layer Act1 and a first gate electrode GE1 at least partially overlapping the first semiconductor layer Act1.

The second thin-film transistor TFT2 may include a second semiconductor layer Act2 and a second gate electrode GE2 at least partially overlapping the second semiconductor layer Act2. The second gate electrode GE2 may include a second lower gate electrode GE2a and a second upper gate electrode GE2b.

In an embodiment, the first semiconductor layer Act1 of the first thin-film transistor TFT1 and the second semiconductor layer Act2 of the second thin-film transistor TFT2 may respectively include different materials from each other. As an example, the first semiconductor layer Act1 may include a silicon semiconductor material, and the second semiconductor layer Act2 may include an oxide semiconductor material.

The first capacitor Cst may include the first capacitor electrode CE1 and the second capacitor electrode CE2. The first capacitor Cst may overlap the first thin-film transistor TFT1.

The substrate 100 may include a glass material, a ceramic material, metal, or a flexible or bendable material. In the case where the substrate 100 is flexible or bendable, the substrate 100 may include a polymer resin including polyethersulfone, polyacrylate, polyetherimide, polyethylene naphthalate, polyethylene terephthalate, polyphenylene sulfide, polyarylate, polyimide, polycarbonate, and cellulose acetate propionate.

The substrate 100 may have a single-layered structure or a multi-layered structure of the above materials, and may further include an inorganic layer in case of the multi-layered structure. In an embodiment, the substrate 100 may have a structure of an organic material/an inorganic material/an organic material.

A barrier layer (not shown) may be further disposed between the substrate 100 and a buffer layer 110. The barrier layer may be configured to prevent or reduce impurities from below the substrate 100, penetrating the first semiconductor layer Act1 and the second semiconductor layer Act2. The barrier layer may include an inorganic material, an organic material, or an organic/inorganic composite material, and include a single layer or a multi-layer including an inorganic material and an organic material, the inorganic material including oxide or nitride.

A bottom metal layer BML may be disposed between the substrate 100 and the buffer layer 110. The bottom metal layer BML may include a conductive material including molybdenum (Mo), aluminum (Al), copper (Cu), and titanium (Ti) and include a single layer or a multi-layer including the above materials.

The bottom metal layer BML may overlap at least a portion of the first semiconductor layer Act1. The bottom metal layer BML may protect the first semiconductor layer Act1. The bottom metal layer BML may be configured to receive an arbitrary (or preset) voltage. Due to the bottom metal layer BML to which an arbitrary voltage is applied, unnecessary charge may be prevented from being accumulated on the first semiconductor layer Act1 while the sub-pixel circuit is driven, wherein the pixel circuit includes both an n-channel MOSFET and a p-channel MOSFET. As a result, the characteristics of the first thin-film transistor TFT1 including the first semiconductor layer Act1 may be stably maintained.

The first semiconductor layer Act1 may be disposed on the buffer layer 110. The first semiconductor layer Act1 may include amorphous silicon or polycrystalline silicon. The first semiconductor layer Act1 may include a channel region, a drain region, and a source region, the drain region and the source region being on two opposite sides of the channel region. The source region and the drain region may each be regions doped with dopants. The first semiconductor layer Act1 may include a single layer or a multi-layer.

A first gate insulating layer 111 may be disposed on the first semiconductor layer Act1. The first gate insulating layer 111 may include an inorganic insulating layer including an inorganic insulating material such as silicon oxide, silicon nitride and/or silicon oxynitride, and include a single layer or a multi-layered structure including the above material. In an embodiment, the first gate insulating layer 111 may be a first insulating layer.

The first gate electrode GE1 and the first capacitor electrode CE1 may be disposed on the first gate insulating layer 111. In an embodiment, the first gate electrode GE1 may be integrally formed with the first capacitor electrode CE1. The first gate electrode GE1 may perform a function of the first capacitor electrode CE1, or the first capacitor electrode CE1 may perform a function of the first gate electrode GE1.

The first gate electrode GE1 and the first capacitor electrode CE1 may include aluminum (Al), platinum (Pt), palladium (Pd), silver (Ag), magnesium (Mg), gold (Au), Nickel (Ni), neodymium (Nd), iridium (Ir), chrome (Cr), lithium (Li), calcium (Ca), molybdenum (Mo), titanium (Ti), tungsten (W), and/or copper (Cu), and include a single layer or a multi-layer including the above materials.

A first interlayer insulating layer 113 may be disposed on the first gate electrode GE1 and/or the first capacitor electrode CE1. The first interlayer insulating layer 113 may include an inorganic insulating layer including an inorganic insulating material such as silicon oxide, silicon nitride and/or silicon oxynitride, and include a single layer or a multi-layered structure including the above material. In an embodiment, the first interlayer insulating layer 113 may be a second-1 insulating layer.

The second capacitor electrode CE2 may be disposed on the first interlayer insulating layer 113. The second capacitor electrode CE2 may include aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), and/or copper (Cu), and include a single layer or a multi-layer including the above materials.

The second capacitor electrode CE2 may overlap the first gate electrode GE1 and/or the first capacitor electrode CE1. In FIG. 3, the second capacitor electrode CE2 may overlap the first capacitor electrode CE1 with the first interlayer insulating layer 113 therebetween, and constitute a capacitance. In this case, the first interlayer insulating layer 113 may serve as a dielectric layer.

A second interlayer insulating layer 117a may be disposed on the second capacitor electrode CE2. The second interlayer insulating layer 117a may include an inorganic insulating layer including an inorganic insulating material such as silicon oxide, silicon nitride and/or silicon oxynitride, and have a single-layered structure or a multi-layered structure including the above material. As an example, the second interlayer insulating layer 117a may be a single layer of silicon nitride. In an embodiment, the second interlayer insulating layer 117a may be a second-2 insulating layer. The first interlayer insulating layer 113 and the second interlayer insulating layer 117a may be a second insulating layer.

The first hole H1 and a second hole H2 may be defined in the insulating layer between the first semiconductor layer Act1 and the second semiconductor layer Act2. As an example, the first hole H1 and the second hole H2 may be defined in the first gate insulating layer 111, the first interlayer insulating layer 113, and the second interlayer insulating layer 117a, and may pass through the first gate insulating layer 111, the first interlayer insulating layer 113, and the second interlayer insulating layer 117a. Each of the first hole H1 and the second hole H2 may overlap a source region or a drain region of the first semiconductor layer Act1. As an example, the first hole H1 may overlap one of the source region and the drain region of the first semiconductor layer Act1, and the second hole H2 may overlap the other of the source region and the drain region of the first semiconductor layer Act1.

A third interlayer insulating layer 117b may be disposed on the second interlayer insulating layer 117a. The third interlayer insulating layer 117b may include an inorganic insulating layer including an inorganic insulating material such as silicon oxide, silicon nitride and/or silicon oxynitride, and have a single-layered structure or a multi-layered structure including the above material. The third interlayer insulating layer 117b may be an inorganic insulating layer having relatively small hydrogen content compared to other inorganic insulating layers of the display apparatus. As an example, the third interlayer insulating layer 117b may be a single layer of silicon oxide. In an embodiment, the third interlayer insulating layer 117b may be a fifth insulating layer.

The third interlayer insulating layer 117b may fill at least a portion of each of the first hole H1 and the second hole H2. In other words, a portion of the third interlayer insulating layer 117b may fill at least a portion of the first hole H1 and the second hole H2. The third interlayer insulating layer 117b may cover the inner lateral surface of the insulating layer forming the first hole H1 and the second hole H2. The third interlayer insulating layer 117b may cover the inner surfaces of the first gate insulating layer 111, the first interlayer insulating layer 113, and the second interlayer insulating layer 117a forming the first hole H1 and the second hole H2.

The second semiconductor layer Act2 may be disposed on the third interlayer insulating layer 117b. The second semiconductor layer Act2 may include an oxide semiconductor material. The second semiconductor layer Act2 may include, for example, an oxide of at least one of indium (In), gallium (Ga), stannum (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn). As an example, the second semiconductor layer Act2 may be an ITZO (InSnZnO) semiconductor layer, an IGZO (InGaZnO) semiconductor layer and the like.

The second semiconductor layer Act2 may include a channel region, a drain region, and a source region, the drain region and the source region being on two opposite sides of the channel region. The second semiconductor layer Act2 may include a single layer or a multi-layer.

The second gate electrode GE2 may be disposed under and/or on the second semiconductor layer Act2. The second lower gate electrode GE2a may be disposed below the second semiconductor layer Act2. The second upper gate electrode GE2b may be disposed over the second semiconductor layer Act2. In an embodiment, the second upper gate electrode GE2b may be the second gate electrode, and the second lower gate electrode GE2a may be a third gate electrode.

The second lower gate electrode GE2a may include the same material as that of the second capacitor electrode CE2, and be disposed on the same layer (e.g., the first interlayer insulating layer 113). Because the second semiconductor layer Act2 including an oxide semiconductor material is vulnerable to light, the second semiconductor layer Act2 may be protected by the second lower gate electrode GE2a. The second lower gate electrode GE2a may prevent a photo current from being induced to the second semiconductor layer Act2 by external light incident from above the substrate 100, and thus, prevent device characteristics of the second thin-film transistor TFT2 including an oxide semiconductor material from changing.

The second upper gate electrode GE2b may be disposed on a second gate insulating layer 119. The second upper gate electrode GE2b may overlap the second lower gate electrode GE2a with the second gate insulating layer 119 therebetween. The second upper gate electrode GE2b may include aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), and/or copper (Cu), and include a single layer or a multi-layer including the above materials. In an embodiment, the second gate insulating layer 119 may be a third insulating layer.

Although it is shown in FIG. 3 that the second gate insulating layer 119 is disposed over the entire surface of the substrate 100 to cover the second semiconductor layer Act2, the second gate insulating layer 119 may be patterned to overlap a portion of the second semiconductor layer Act2 in an embodiment. As an example, the second gate insulating layer 119 may be patterned to overlap the channel region of the second semiconductor layer Act2.

A fourth interlayer insulating layer 121 may be disposed on the second upper gate electrode GE2b. The fourth interlayer insulating layer 121 may include an inorganic insulating layer including an inorganic insulating material such as silicon oxide, silicon nitride and/or silicon oxynitride, and include a single layer or a multi-layered structure including the above material. In an embodiment, the fourth interlayer insulating layer 121 may be a fourth insulating layer.

A first connection electrode E1, a second connection electrode E2, a third connection electrode E3, and a fourth connection electrode E4 may be disposed on the fourth interlayer insulating layer 121. The first connection electrode E1 to the fourth connection electrode E4 may include aluminum (Al), platinum (Pt), palladium (Pd), silver (Ag), magnesium (Mg), gold (Au), Nickel (Ni), neodymium (Nd), iridium (Ir), chrome (Cr), lithium (Li), calcium (Ca), molybdenum (Mo), titanium (Ti), tungsten (W), and/or copper (Cu), and include a single layer or a multi-layer including the above materials. As an example, the first connection electrode E1 to the fourth connection electrode E4 may have a triple-layered structure in which a titanium layer, an aluminum layer, and a titanium layer are stacked.

The first contact hole PCNT1 and a second contact hole PCNT2 may be defined in the insulating layer between the first connection electrode E1 and the second connection electrode E2, and the first semiconductor layer Act1. Referring to FIGS. 3 and 4, the first contact hole PCNT1 may be within and overlap the first hole H1. The second contact hole PCNT2 may be within and overlap the second hole H2. The first contact hole PCNT1 and the second contact hole PCNT2 may have widths less than the widths of the first hole H1 and the second hole H2, respectively. That is, the first hole H1 and the second hole H2 may have the widths greater than the widths of the first contact hole PCNT1 and the second contact hole PCNT2, respectively. As an example, as shown in FIG. 4, a width W1 of the first hole H1 may be greater than a width W2 of the first contact hole PCNT1. In other words, the first contact hole PCNT1 may completely overlap the first hole H1. The second contact hole PCNT2 may completely overlap the second hole H2.

In an embodiment, a difference between the width W1 of the first hole H1 and the width W2 of the first contact hole PCNT1 may be about 0.8 μm to about 1.8 μm. In an embodiment, the width W1 of the first hole H1 may be about 2.6 μm to about 3.2 μm.

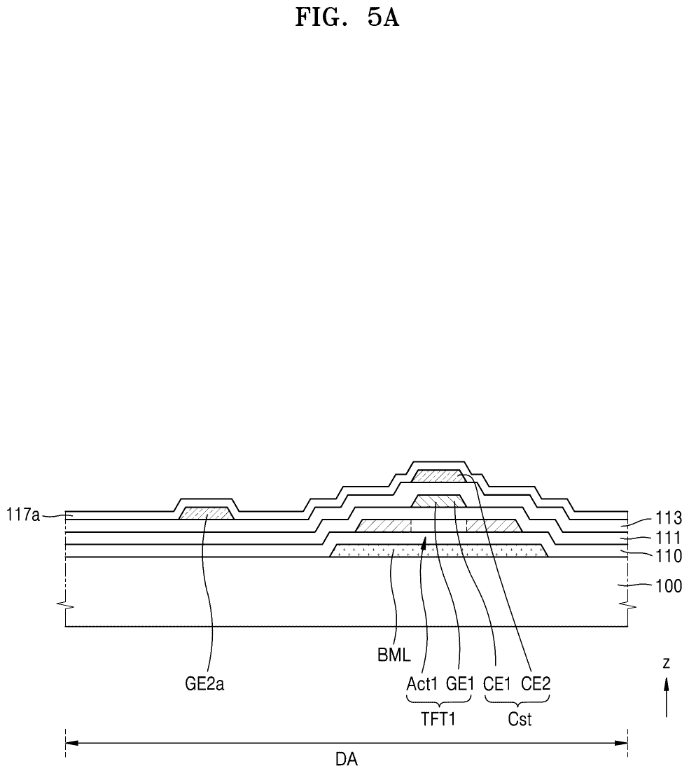

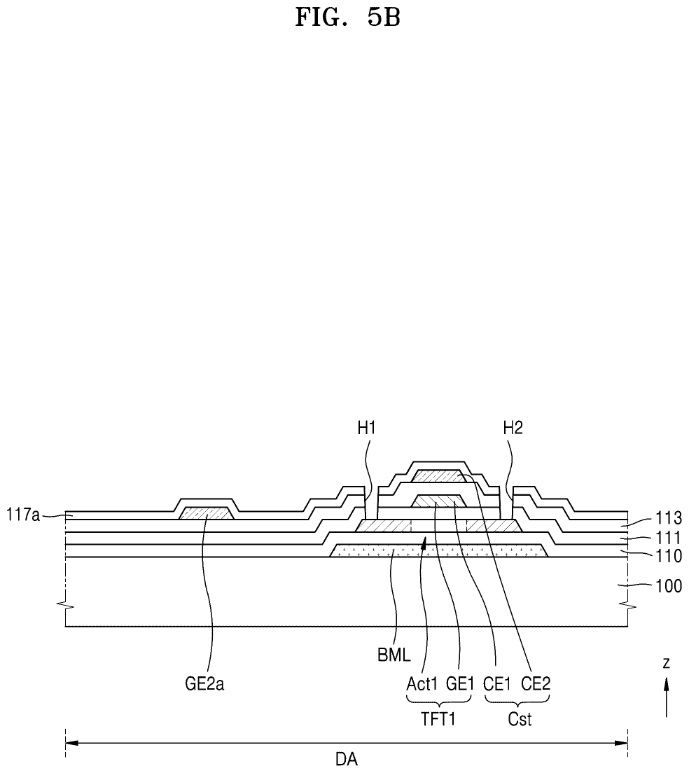

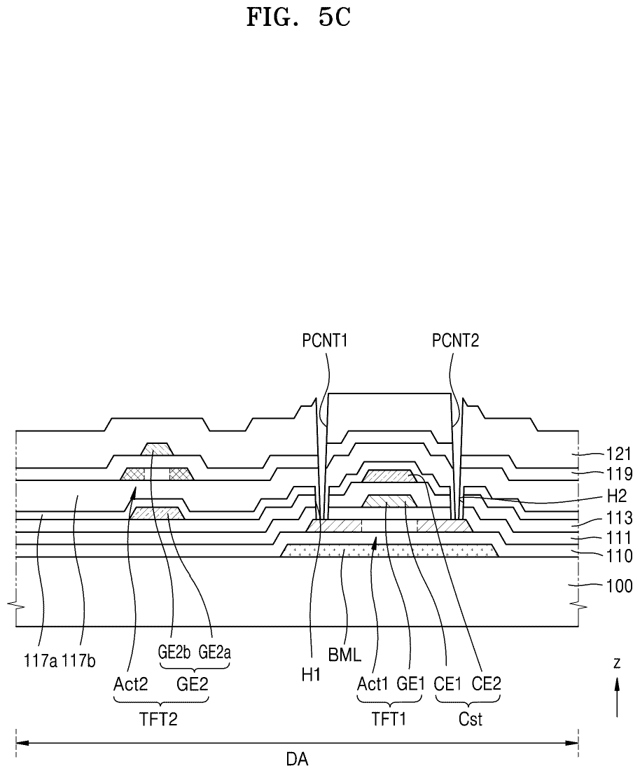

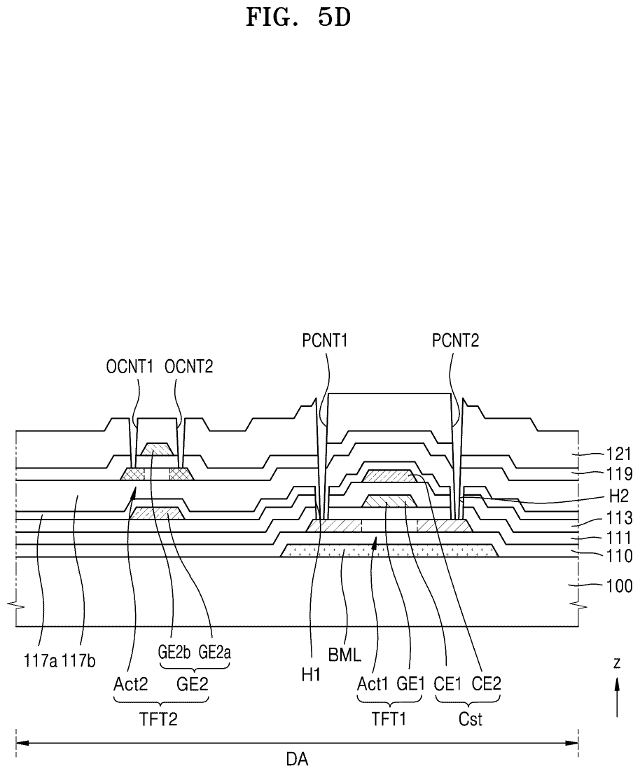

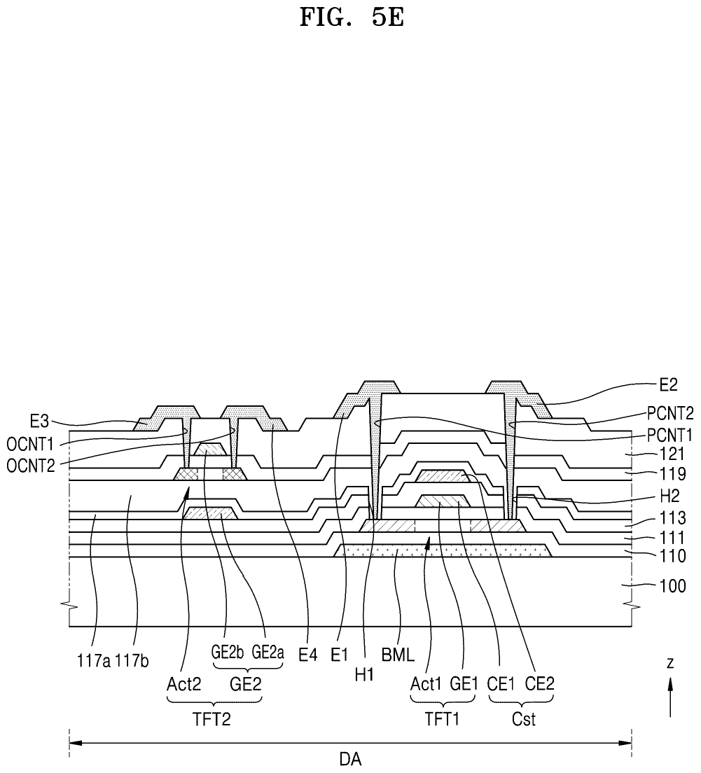

Because the first hole H1 and the second hole H2 have greater widths than those of the first contact hole PCNT1 and the second contact hole PCNT2, hydrogen emission from the first semiconductor layer Act1 through the first hole H1 and the second hole H2 may be swiftly performed in a heat treatment process described below with reference to FIG. 5B.

The first contact hole PCNT1 and the second contact hole PCNT2 may be defined in the third interlayer insulating layer 117b, the second gate insulating layer 119, and the fourth interlayer insulating layer 121 and may pass through the third interlayer insulating layer 117b, the second gate insulating layer 119, and the fourth interlayer insulating layer 121. The first contact hole PCNT1 may pass through a portion of the third interlayer insulating layer 117b filling the first hole H1. The second contact hole PCNT2 may pass through a portion of the third interlayer insulating layer 117b filling the second hole H2. Each of the first contact hole PCNT1 and the second contact hole PCNT2 may overlap the source region or the drain region of the first semiconductor layer Act1.

The first connection electrode E1 may be electrically connected to the first semiconductor layer Act1 through the first contact hole PCNT1. A portion of the first electrode E1 may fill at least a portion of the first contact hole PCNT1. A portion of the first electrode E1 may be buried in the first contact hole PCNT1. The first connection electrode E1 may be in contact with the first semiconductor layer Act1 through the first contact hole PCNT1. A portion of the first connection electrode E1 filling the first contact hole PCNT1 may be in contact with the third interlayer insulating layer 117b filling the first hole H1.

The second connection electrode E2 may be electrically connected to the first semiconductor layer Act1 through the second contact hole PCNT2. A portion of the second electrode E2 may fill at least a portion of the second contact hole PCNT2. A portion of the second electrode E2 may be buried in the second contact hole PCNT2. The second connection electrode E2 may be in contact with the first semiconductor layer Act1 through the second contact hole PCNT2. A portion of the second connection electrode E2 filling the second contact hole PCNT2 may be in contact with the third interlayer insulating layer 117b filling the second hole H2.

A third contact hole OCNT1 and a fourth contact hole OCNT2 may be defined in the insulating layer between the third connection electrode E3 and the fourth connection electrode E4, and the second semiconductor layer Act2.

The third contact hole OCNT1 and the fourth contact hole OCNT2 may be defined in the second gate insulating layer 119 and the fourth interlayer insulating layer 121 and may pass through the second gate insulating layer 119 and the fourth interlayer insulating layer 121. Each of the third contact hole OCNT1 and the fourth contact hole OCNT2 may overlap the source region or the drain region of the second semiconductor layer Act2.

The third connection electrode E3 may be electrically connected to the second semiconductor layer Act2 through the third contact hole OCNT1. A portion of the third electrode E3 may fill at least a portion of the third contact hole OCNT1. A portion of the third electrode E3 may be buried in the third contact hole OCNT1. The third connection electrode E3 may be in contact with the second semiconductor layer Act2 through the third contact hole OCNT1.

The fourth connection electrode E4 may be electrically connected to the second semiconductor layer Act2 through the fourth contact hole OCNT2. A portion of the fourth electrode E4 may fill at least a portion of the fourth contact hole OCNT2. A portion of the fourth electrode E4 may be buried in the fourth contact hole OCNT2. The fourth connection electrode E4 may be in contact with the second semiconductor layer Act2 through the fourth contact hole OCNT2.

A planarization layer 123 may be disposed on the first connection electrode E1 to the fourth connection electrode E4. The planarization layer 123 may include a single layer or a multi-layer including an organic material and provide a flat upper surface. The planarization layer 123 may include a general-purpose polymer such as benzocyclobutene (BCB), polyimide, hexamethyldisiloxane (HMDSO), polymethylmethacrylate (PMMA) or polystyrene (PS), polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, and a blend thereof.

A light-emitting diode may be disposed on the planarization layer 123. The light-emitting diode may be an organic light-emitting diode OLED. The organic light-emitting diode OLED may include a sub-pixel electrode 210, an intermediate layer 220, and an opposite electrode 230, wherein the intermediate layer 220 includes an emission layer.

The sub-pixel electrode 210 may be a (semi) light-transmissive electrode or a reflective electrode. In an embodiment, the sub-pixel electrode 210 may include a reflective layer and a transparent or semi-transparent electrode layer on the reflective layer, wherein the reflective layer includes at least one of Ag, Mg, Al, Pt, Pd, Au, Ni, Nd, Ir, Cr, and compound thereof. The transparent or semi-transparent electrode layer may include at least one of indium tin oxide (ITO), indium zinc oxide (IZO), zinc oxide (ZnO), indium oxide (In₂O₃), indium gallium oxide (IGO), and aluminum zinc oxide (AZO). In an embodiment, the sub-pixel electrode 210 may include ITO/Ag/ITO.

The sub-pixel electrode 210 may be connected to the first connection electrode E1 through a contact hole formed in the planarization layer 123. The sub-pixel electrode 210 may be electrically connected to the first semiconductor layer Act1 through the first connection electrode E1.

A bank layer 127 may be disposed on the planarization layer 123. In addition, the bank layer 127 may prevent arcs and the like from occurring at the edges of the sub-pixel electrode 210 by increasing a distance between the edges of the sub-pixel electrode 210 and the opposite electrode 230 over the sub-pixel electrode 210.

The bank layer 127 may include an organic insulating material such as polyimide, an acrylic resin, benzocyclobutene, a phenolic resin, and the like and be formed by using spin coating and the like. The bank layer 127 may include an organic insulating material. The bank layer 127 may include an inorganic insulating material such as silicon oxide, silicon nitride, or silicon oxynitride. In other embodiments, the bank layer 127 may include an organic insulating material and an inorganic insulating material. In an embodiment, the bank layer 127 may include a light-blocking material and be provided in black. In the case where the bank layer 127 includes a light-blocking material, external light reflection by metal structures disposed below the bank layer 127 may be reduced.

The intermediate layer 220 may be disposed in an opening of the bank layer 127. The intermediate layer 220 may include an emission layer. The emission layer may include an organic material including a fluorescent or phosphorous material emitting red, green, blue, or white light. The emission layer may include a polymer organic material or a low molecular weight organic material. Functional layers may be selectively further arranged under and on the emission layer, the functional layers including a hole transport layer (HTL), a hole injection layer (HIL), an electron transport layer (ETL), or an electron injection layer (EIL).

The intermediate layer 220 may be disposed to correspond to the plurality of sub-pixel electrodes 210. However, the embodiment is not limited thereto. The intermediate layer 220 may include a layer that is one body over the plurality of sub-pixel electrodes 210. However, various modifications may be made.

The opposite electrode 230 may be a light-transmissive electrode or a reflective electrode. In an embodiment, the opposite electrode 230 may be a transparent or semi-transparent electrode and may include a metal thin film including Li, Ca, LiF/Ca, LiF/Al, Al, Ag, Mg, or compound thereof and having a small work function. In addition, a transparent conductive oxide (TCO) layer such as ITO, IZO, ZnO, or In₂O₃ may be further arranged on the metal thin film. The opposite electrode 230 may be arranged over the display area DA and disposed on the intermediate layer 220 and the bank layer 127. The opposite electrode 230 may be integrally formed over a plurality of organic light-emitting diodes to correspond to a plurality of sub-pixel electrodes 210.

The organic light-emitting diode OLED may be covered by an encapsulation layer (not shown). The encapsulation layer may include at least one organic encapsulation layer and at least one inorganic encapsulation layer. The inorganic encapsulation layers may include an inorganic material including aluminum oxide, titanium oxide, tantalum oxide, hafnium oxide, zinc oxide, silicon oxide, silicon nitride, silicon oxynitride, and the like. The organic encapsulation layer may include a polymer-based material. The polymer-based material may include an acryl-based resin such as polymethylmethacrylate and poly acrylic acid, an epoxy-based resin, polyimide, and polyethylene. In an embodiment, the organic encapsulation layer may include acrylate polymer.

FIGS. 5A to 5E are cross-sectional views showing a process of manufacturing the display apparatus according to an embodiment. Through the processes shown in FIGS. 5A to 5E, the display apparatus of FIG. 3 may be formed.

Referring to FIG. 5A, the first thin-film transistor TFT1, the first capacitor Cst, and the second lower gate electrode GE2a may be formed on the substrate 100 in the display area DA.

The bottom metal layer BML may be formed on the substrate 100, and the buffer layer 110 may be formed. The first semiconductor layer Act1 of the first thin-film transistor TFT1 may be formed on the buffer layer 110. The first gate insulating layer 111 covering the first semiconductor layer Act1 may be formed, and the first gate electrode layer GE1 may be formed. The first gate electrode GE1 may be integrally formed with the first capacitor electrode CE1 of the first capacitor Cst. Accordingly, the first thin-film transistor TFT1 may be formed.

The first interlayer insulating layer 113 covering the first gate electrode layer GE1 and/or the first capacitor electrode CE1 may be formed. The second capacitor electrode CE2 and the second lower gate electrode GE2a may be formed on the first interlayer insulating layer 113. The second interlayer insulating layer 117a may be formed to cover the second capacitor electrode CE2 and the second lower gate electrode GE2a.

Referring to FIG. 5B, the first hole H1 and the second hole H2 may be formed. The first hole H1 and the second hole H2 may pass through the first gate insulating layer 111, the first interlayer insulating layer 113, and the second interlayer insulating layer 117a. Each of the first hole H1 and the second hole H2 may be above and overlap a source region or a drain region of the first semiconductor layer Act1.

The first hole H1 and the second hole H2 are formed and the stacked structure may be heat-treated. As an example, the first semiconductor layer Act1 may be heat-treated. In the case where the first semiconductor layer Act1 is heat-treated, hydrogen (H) bonded to silicon (Si) of the first semiconductor layer Act1 including a silicon semiconductor material may be released through the first hole H1 and the second hole H2. Device characteristics of the first thin-film transistor TFT1 may be controlled by intentionally inducing defects in the first semiconductor layer Act1. Specifically, the device characteristics of the first thin-film transistor TFT1 may be improved by securing a dynamic range and optimizing sensitivity of the first thin-film transistor TFT1.

In an embodiment, the heat treatment process may be performed at 380° C. for about 15 minutes.

Referring to FIG. 5C, the third interlayer insulating layer 117b may be formed on the second interlayer insulating layer 117a. The third interlayer insulating layer 117b may fill at least a portion of each of the first hole H1 and the second hole H2. A portion of the third interlayer insulating layer 117b may fill at least a portion of the first hole H1 and the second hole H2. The third interlayer insulating layer 117b may cover the inner surfaces of the first gate insulating layer 111, the first interlayer insulating layer 113, and the second interlayer insulating layer 117a forming the first hole H1 and the second hole H2.

The second semiconductor layer Act2 may be formed on the third interlayer insulating layer 117b. The second semiconductor layer Act2 may overlap the second lower gate electrode GE2a. The second gate insulating layer 119 covering the second semiconductor layer Act2 may be formed. The second upper gate electrode GE2b may be formed on the second gate insulating layer 119. The second thin-film transistor TFT2 may be formed. The fourth interlayer insulating layer 121 may be formed to cover the second upper gate electrode GE2b.

The first contact hole PCNT1 and the second contact hole PCNT2 may be formed. The first contact hole PCNT1 may be within and overlap the first hole H1. The second contact hole PCNT2 may be within and overlap the second hole H2. The first contact hole PCNT1 and the second contact hole PCNT2 may have widths less than the widths of the first hole H1 and the second hole H2, respectively.

The first contact hole PCNT1 and the second contact hole PCNT2 may pass through the third interlayer insulating layer 117b, the second gate insulating layer 119, and the fourth interlayer insulating layer 121. The first contact hole PCNT1 may pass through a portion of the third interlayer insulating layer 117b filling the first hole H1. The second contact hole PCNT2 may pass through a portion of the third interlayer insulating layer 117b filling the second hole H2. Each of the first contact hole PCNT1 and the second contact hole PCNT2 may overlap the source region or the drain region of the first semiconductor layer Act1.

Referring to FIG. 5D, the third contact hole OCNT1 and the fourth contact hole OCNT2 may be formed. The third contact hole OCNT1 and the fourth contact hole OCNT2 may pass through the second gate insulating layer 119 and the fourth interlayer insulating layer 121. Each of the third contact hole OCNT1 and the fourth contact hole OCNT2 may overlap the source region or the drain region of the second semiconductor layer Act2.

Referring to FIG. 5E, the first connection electrode E1 to the fourth connection electrode E4 may be formed on the fourth interlayer insulating layer 121.

The first connection electrode E1 may be in contact with the first semiconductor layer Act1 through the first contact hole PCNT1. A portion of the first connection electrode E1 filling the first contact hole PCNT1 may be in contact with the third interlayer insulating layer 117b filling the first hole H1.

The second connection electrode E2 may be in contact with the first semiconductor layer Act1 through the second contact hole PCNT2. A portion of the second connection electrode E2 filling the second contact hole PCNT2 may be in contact with the third interlayer insulating layer 117b filling the second hole H2.

The third connection electrode E3 may be in contact with the second semiconductor layer Act2 through the third contact hole OCNT1. The fourth connection electrode E4 may be in contact with the second semiconductor layer Act2 through the fourth contact hole OCNT2.

In a comparative example, both the first thin-film transistor and the second thin-film transistor are formed, holes exposing the first semiconductor layer are formed, a process of heat-treating the first semiconductor layer may be performed. In this case, the holes may be contact holes for allowing the first connection electrode and the second connection electrode to be in contact with the first semiconductor layer. In this case, the insulating layers around the second semiconductor layer may be heat-treated together with the first semiconductor layer during the process of heat-treating the stacked structure. Hydrogen may be released from the first semiconductor layer through the holes, and simultaneously, hydrogen may move from the neighboring insulating layers to the second semiconductor layer. When hydrogen is introduced to the second semiconductor layer including an oxide semiconductor material, a threshold voltage of the second thin-film transistor is reduced and a (−) shift phenomenon may occur. That is, the device characteristics of the second thin-film transistor may deteriorate. Accordingly, the device characteristics of the first thin-film transistor are improved, but the device characteristics of the second thin-film transistor may deteriorate.

However, according to an embodiment, after the first thin-film transistor TFT1 is formed, before the second semiconductor layer Act2 of the second thin-film transistor TFT2 is formed, the first hole H1 and the second hole H2 extending to and exposing the first semiconductor layer Act1 may be formed and heat-treatment may be performed. The second semiconductor layer Act2 of the second thin-film transistor TFT2 and the second upper gate electrode GE2b may be formed, and the first contact hole PCNT1 and the second contact hole PCNT2 respectively overlapping the first hole H1 and the second hole H2 may be formed. The first contact hole PCNT1 and the second contact hole PCNT2 may be holes for respectively allowing the first connection electrode E1 and the second connection electrode E2 to be in contact with the first semiconductor layer Act1. In this case, because the forming of the first hole H1 and the second hole H2 and the heat treatment process are performed before the second semiconductor layer Act2 is formed, the device characteristics of the second thin-film transistor TFT2 may be prevented from being changed by the movement of hydrogen from the neighboring insulating layers to the second semiconductor layer Act2 during the heat treatment. Accordingly, the device characteristics of the first thin-film transistor may be improved, and simultaneously, the device characteristics of the second thin-film transistor may be maintained.

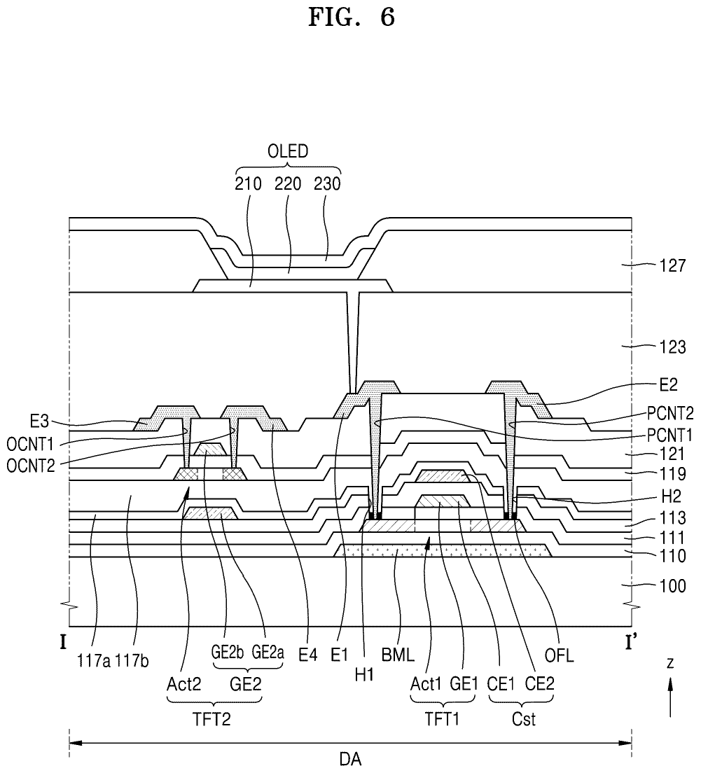

FIG. 6 is a schematic cross-sectional view of the display apparatus according to an embodiment. FIG. 6 is a modified embodiment of FIG. 3. Hereinafter, differences are mainly described and repeated descriptions are omitted.

Referring to FIG. 6, an oxide layer OFL may be disposed on the first semiconductor layer Act1. The oxide layer OFL may be disposed inside the first hole H1 and the second hole H2.

The first contact hole PCNT1 may pass through the oxide layer OFL disposed inside the first hole H1. The second contact hole PCNT2 may pass through the oxide layer OFL disposed inside the second hole H2. The oxide layer OFL may be in contact with a portion of the first connection electrode E1 filling the first contact hole PCNT1. The oxide layer OFL may be in contact with a portion of the second connection electrode E2 filling the second contact hole PCNT2.

The oxide layer OFL may include an oxide. The oxide layer OFL may be configured to prevent hydrogen from being introduced to the first semiconductor layer Act1.

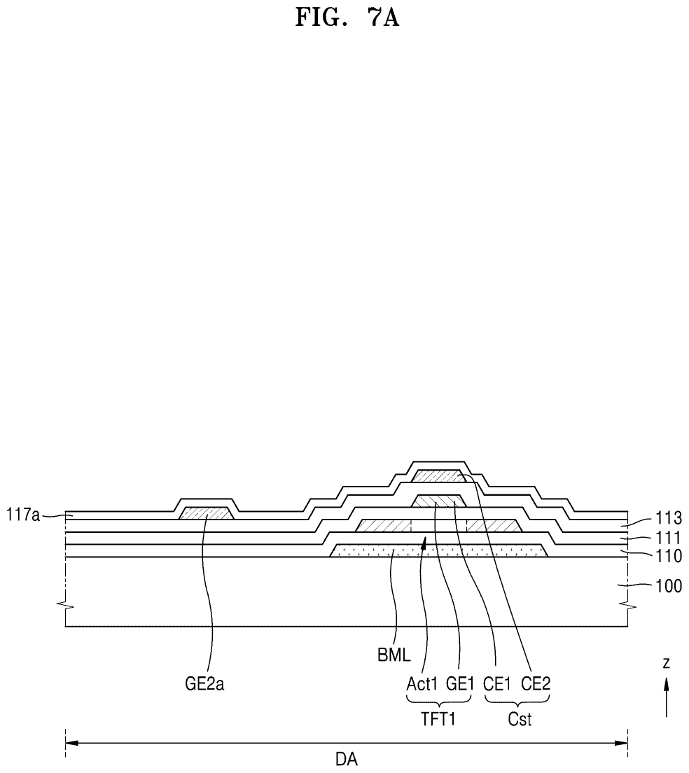

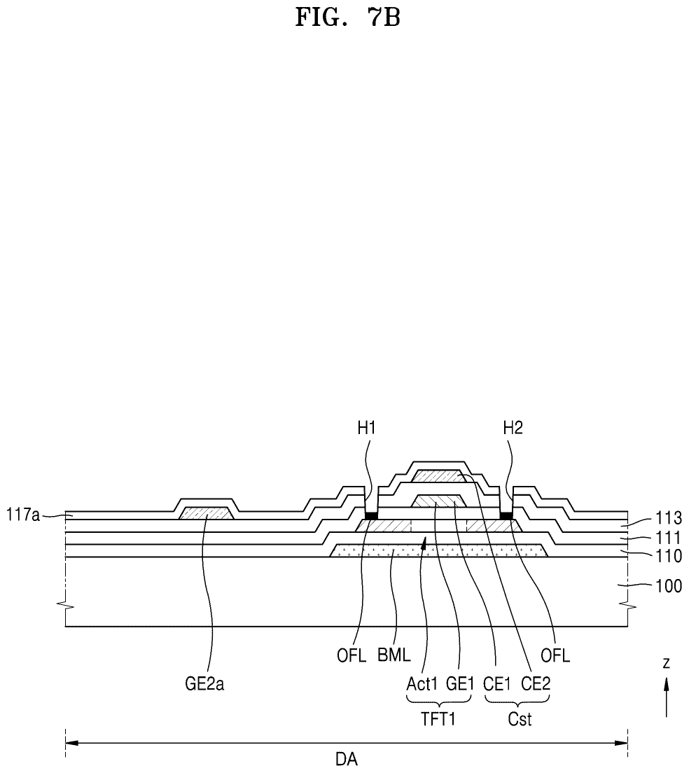

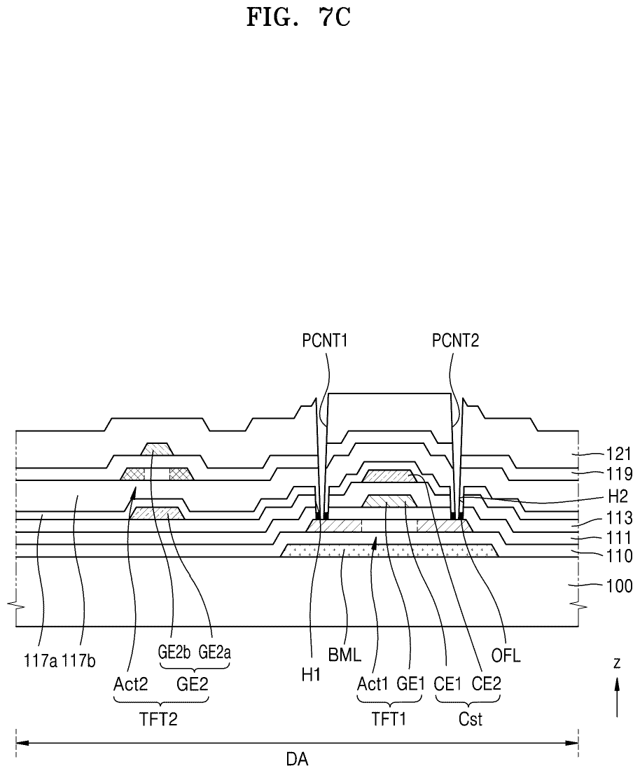

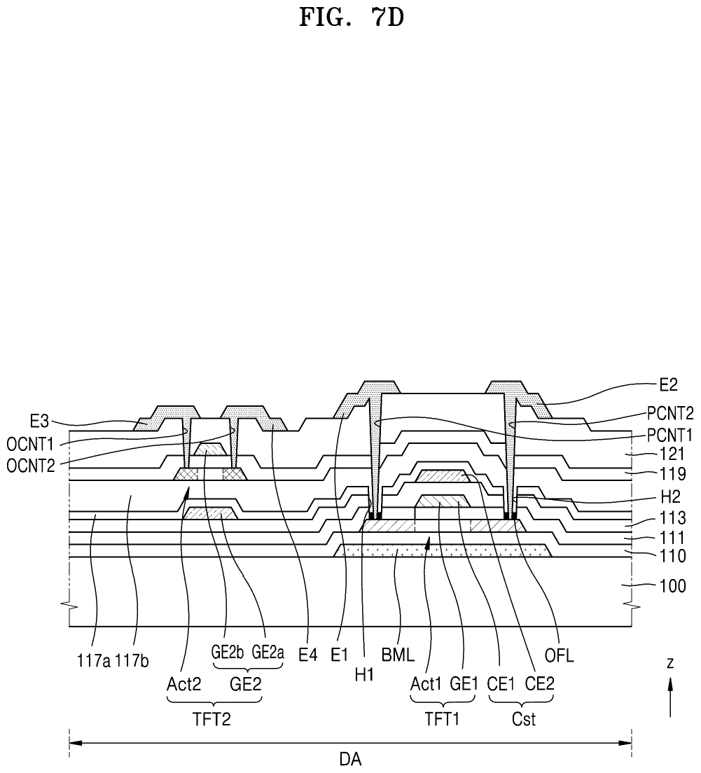

FIGS. 7A to 7D are cross-sectional views showing a process of manufacturing a display apparatus according to an embodiment. Through the processes shown in FIGS. 7A to 7D, the display apparatus of FIG. 6 may be formed. FIGS. 7A to 7D are modified embodiments of FIGS. 5A to 5E. Hereinafter, differences are mainly described and repeated descriptions are omitted.

Referring to FIG. 7A, the first thin-film transistor TFT1, the first capacitor Cst, and the second lower gate electrode GE2a may be formed on the substrate 100 in the display area DA. Also, the buffer layer 110, first gate insulating layer 111, the first interlayer insulating layer 113, and the second interlayer insulating layer 117a may be formed.

The first hole H1 and the second hole H2 are formed, and the stacked structure may be heat-treated. As an example, the first semiconductor layer Act1 may be heat-treated. By allowing hydrogen (H) bonded to silicon (Si) of the first semiconductor layer Act1 to be released through the first hole H1 and the second hole H2, the device characteristics of the first thin film transistor TFT1 may be improved.

Referring to FIG. 7B, the oxide layer OFL may be formed on the first semiconductor layer Act1. The oxide layer OFL may be formed inside the first hole H1 and the second hole H2.

In an embodiment, the forming of the oxide layer OFL may be simultaneously performed with the heat treatment process. As an example, the oxide layer OFL may be formed by controlling the temperature of the heat treatment process to exceed 360° C. and/or controlling the heat treatment process time to exceed 15 minutes.

In an embodiment, the forming of the oxide layer OFL may be performed as a separate process after the heat treatment process. As an example, the oxide layer OFL may be formed by an O₂ plasma process. However, the embodiment is not limited thereto. The forming of the oxide layer OFL may be performed by various known methods.

Referring to FIG. 7C, the second thin-film transistor TFT2 may be formed on the first thin-film transistor TFT1. In addition, the third interlayer insulating layer 117b, the second gate insulating layer 119, and the fourth interlayer insulating layer 121 may be formed.

The first contact hole PCNT1 and the second contact hole PCNT2 may be formed. The first contact hole PCNT1 may be formed within and overlap the first hole H1 and pass through the third interlayer insulating layer 117b, the second gate insulating layer 119, the fourth interlayer insulating layer 121, and the oxide layer OFL. The second contact hole PCNT2 may be formed within and overlap the second hole H2 and pass through the third interlayer insulating layer 117b, the second gate insulating layer 119, the fourth interlayer insulating layer 121, and the oxide layer OFL.

Referring to FIG. 7D, the third contact hole OCNT1 and the fourth contact hole OCNT2 may be formed. The first connection electrode E1 to the fourth connection electrode E4 may be formed. The first connection electrode E1 and the second connection electrode E2 may be in contact with the first semiconductor layer Act1 through the first contact hole PCNT1 and the second contact hole PCNT2. The third connection electrode E3 and the fourth connection electrode E4 may be in contact with the second semiconductor layer Act2 through the third contact hole OCNT1 and the fourth contact hole OCNT2.

According to an embodiment, a display apparatus with improved characteristics of transistors, and a method of manufacturing the display apparatus may be implemented. However, the scope of the disclosure is not limited by this effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a substrate;
a first thin-film transistor disposed over the substrate and including a first semiconductor layer and a first gate electrode;
a second thin-film transistor including a second semiconductor layer and a second gate electrode;
a first insulating layer between the first semiconductor layer and the first gate electrode;
a second insulating layer between the first gate electrode and the second semiconductor layer;
a third insulating layer between the second semiconductor layer and the second gate electrode;
a fourth insulating layer on the second gate electrode;
a first hole above the first semiconductor layer and passing through the first insulating layer and the second insulating layer; and
a second hole within the first hole and passing through the third insulating layer and the fourth insulating layer.

2. The display apparatus of claim 1, wherein a width of the first hole is greater than a width of the second hole.

3. The display apparatus of claim 1, wherein the second thin-film transistor further includes a third gate electrode disposed below the second semiconductor layer and overlapping the second semiconductor layer, and the second insulating layer includes a second-1 insulating layer and a second-2 insulating layer, wherein the second-1 insulating layer is between the first gate electrode and the third gate electrode, and the second-2 insulating layer is on the third gate electrode.

4. The display apparatus of claim 1, further comprising a fifth insulating layer between the second insulating layer and the second semiconductor layer,
wherein the fifth insulating layer fills at least a portion of the first hole.

5. The display apparatus of claim 4, wherein the fifth insulating layer includes an inorganic insulating material.

6. The display apparatus of claim 4, further comprising an electrode disposed on the fourth insulating layer and overlapping the first semiconductor layer,
wherein the electrode is in contact with the first semiconductor layer through the second hole.

7. The display apparatus of claim 6, wherein the electrode is in contact with the fifth insulating layer filling the at least portion of the first hole.

8. The display apparatus of claim 1, wherein the first semiconductor layer includes a silicon semiconductor material, and the second semiconductor layer includes an oxide semiconductor material.

9. The display apparatus of claim 1, further comprising an oxide layer disposed on the first semiconductor layer and disposed in the first hole.

10. The display apparatus of claim 9, wherein the second hole passes through the oxide layer.

11. A method of manufacturing a display apparatus, the method comprising:
forming a first semiconductor layer of a first thin-film transistor over a substrate;
forming a first insulating layer on the first semiconductor layer;
forming a first gate electrode of the first thin-film transistor on the first insulating layer;
forming a second insulating layer on the first gate electrode;
forming a first hole above the first semiconductor layer and passing through the first insulating layer and the second insulating layer;
heat-treating the first semiconductor layer;
forming a second semiconductor layer of a second thin-film transistor on the second insulating layer;
forming a third insulating layer on the second semiconductor layer;
forming a second gate electrode of the second thin-film transistor on the third insulating layer;
forming a fourth insulating layer on the second gate electrode; and
forming a second hole within the first hole and passing through the third insulating layer and the fourth insulating layer.

12. The method of claim 11, wherein a width of the first hole is greater than a width of the second hole.

13. The method of claim 11, further comprising forming a third gate electrode of the second thin-film transistor disposed below the second semiconductor layer and overlapping the second semiconductor layer,
wherein the forming of the second insulating layer includes:
forming a second-1 insulating layer between the first gate electrode and the third gate electrode; and
forming a second-2 insulating layer on the third gate electrode.

14. The method of claim 11, further comprising forming a fifth insulating layer between the second insulating layer and the second semiconductor layer,
wherein the fifth insulating layer fills at least a portion of the first hole.

15. The method of claim 14, wherein the fifth insulating layer includes an inorganic insulating material.

16. The method of claim 14, wherein the second hole passes through the fifth insulating layer filling at least a portion of the first hole.

17. The method of claim 14, further comprising forming an electrode overlapping the first semiconductor layer on the fourth insulating layer,
wherein the electrode is in contact with the first semiconductor layer through the second hole.

18. The method of claim 17, wherein the electrode is in contact with the fifth insulating layer filling the at least portion of the first hole.

19. The method of claim 11, further comprising, before the forming of the second semiconductor layer, forming an oxide layer on the first semiconductor layer and disposed in the first hole.

20. The method of claim 19, wherein the second hole passes through the oxide layer.
